(19) United States
(12) Patent Application Publication
(10) Pub. No.: US 2015/0081963 A1
(43) Pub. Date: Mar. 19, 2015

(54) Allocating a Timeslot

(71) Applicant: Hangzhou H3C Technologies Co., Ltd., Hangzhou (CN)

(72) Inventor: Bin Wang, Beijing (CN)

(21) Appl. No.: 14/484,394

(22) Filed: Sep. 12, 2014

(30) Foreign Application Priority Data
Sep. 16, 2013 (CN) 201310420988.2

(51) Int. Cl. G11C 7/22; G11C 11/408

(52) U.S. Cl. CPC G11C 7/225; G11C 11/4087
USPC 711/104

(57) ABSTRACT

An interface of a receiving module in a FPGA chip receives data. The interface writes the data to a buffer of the receiving module, in which the buffer is implemented by a single piece of RAM of which a bit width is B-bit. A first sub-module of the receiving module reads B-bit data from the buffer each timeslot and writes the B-bit data to a data storage of a scheduling module in the FPGA chip, in which the data storage is formed by M pieces of RAM which are numbered in sequence, each of the M pieces of RAM is divided into address spaces which are numbered in sequence, and the timeslot is allocated by a timing generator of the scheduling module and a timeslot cycle is N. A second sub-module of the scheduling module reads data from the data storage, processes the data read out and sends the processed data.

### CROSS-REFERENCE TO RELATED APPLICATIONS

This application claims priority to China Patent Application No. 201310420988.2, filed on Sep. 16, 2013, entitled “A method and device for saving resource overhead with timeslot arbitration”, which is incorporated herein by reference.

### BACKGROUND

During implementation of communication technologies, functional processing on a plurality of interfaces or modules is often involved. Usually, processing methods associated with these interfaces or modules are the same.

For example, a plurality of E1 interfaces are associated with a chip and functional processing methods on these E1 interfaces are the same. In another example, a plurality of Gigabit Ethernet (GE) interfaces are associated with a chip and functional processing methods on these GE interfaces are the same, as well.

### BRIEF DESCRIPTION OF THE DRAWINGS

Features of the present disclosure are illustrated by way of example and not limited in the following figure(s), in which like numerals indicate like elements, in which:

FIG. 1 is a flowchart illustrating a method of timeslot division, according to various examples of the present disclosure.

FIG. 2 is a diagram illustrating an implementation environment for the method of timeslot division, according to various examples of the present disclosure.

FIG. 3 is a diagram illustrating a data storage space, according to various examples of the present disclosure.

FIG. 4 is a diagram illustrating a timeslot operating process, according to various examples of the present disclosure.

FIG. 5 is a diagram illustrating a data storage space of a method example, according to various examples of the present disclosure.

FIG. 6 is a flowchart illustrating a method example, according to various examples of the present disclosure.

FIG. 7 is a diagram illustrating a structure of a device, according to various examples of the present disclosure.

### DETAILED DESCRIPTION

Hereinafter, the present disclosure will be described in further detail with reference to the accompanying drawings and examples.

In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure. As used herein, the term “includes” means includes but not limited to, and the term “including” means including but not limited to. The term “based on” means based at least in part on. In addition, the terms “a” and “an” are intended to denote at least one of a particular element.

Taking reception functions of the GE interfaces as an example, according to the example, receiving interfaces (hereinafter may be referred to as IF interfaces) may receive data first. In one example, 8-bit data at each interface may be converted to 256-bit data through a register and stored in a buffer of a receiving module, which is a high bandwidth function module and is used instead of a separate functional module for each receiving interface.

In one example the buffer may be a First in First out (FIFO) data queue. In one example, when data within 256/8=32 clock cycles is received, the data is written once to the FIFO data queue. The data written to the FIFO data queue each time is 256 bits. The data received within each clock cycle may be 8 bits. In the example, the data at each interface is stored in a FIFO data queue, and the data at interfaces are respectively stored in FIFO data queues. In this case, the bit width of each FIFO data queue is 256-bit. In one example there are 16 GE interfaces and 16 corresponding data queues.

Then, a Round Robin (RR) module reads the data in the FIFO data queues in turn and stores the data in a data storage BUFFER. After the data at the interfaces is aggregated into the BUFFER, GE medium access control (MAC) functions are implemented, including cyclic redundancy check (CRC) calculation, packet length detection, frame information extraction, and so like.

However, in the example, the RR module reads the data from the 16 receiving interfaces, which is fairly complex and cannot meet requirements of hardware timing, and resource consumption is also very large due to the wide bit width of the bus. Moreover, the bit width of a random access memory (RAM) used for implementing the FIFO data queue in the receiving module is 256-bit which is so wide that multiple pieces of RAM are required to implement the 256-bit RAM, which leads to excessive consumptions of RAM resources.

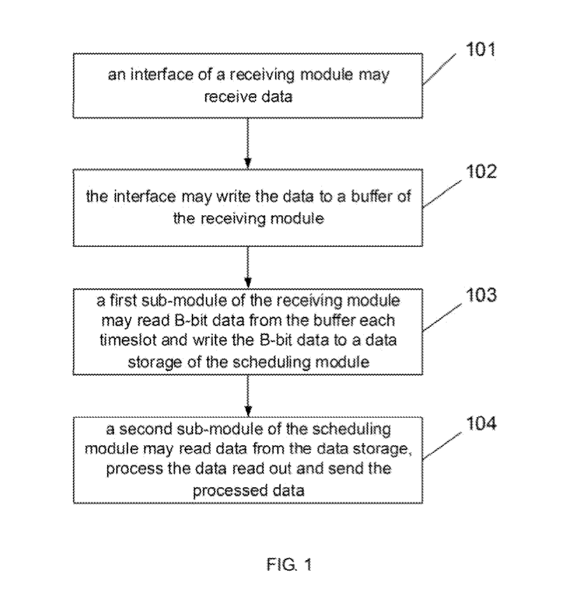

According to various examples of the present disclosure, a method of timeslot division is described, so that the resources can be saved. FIG. 1 is a flowchart illustrating the method of timeslot division. The method may be applied to a Field-Programmable Gate Array (FPGA) chip, in which the FPGA chip may include a scheduling module and N receiving modules which are numbered in sequence, N is greater than or equal to 1. As shown in FIG. 1, the method may include following operations.

At block 101, an interface of a receiving module may receive data.

At block 102, the interface may write the data to a buffer of the receiving module. In this case, the buffer may for example be a First in First out (FIFO) buffer and the FIFO buffer is implemented by a single piece of RAM of which a bit width is B-bit.

At block 103, a first sub-module of the receiving module may read B-bit data from the FIFO buffer each timeslot and write the B-bit data to a data storage of the scheduling module. In this case, the data storage is formed by M pieces of RAM which are numbered in sequence, each of the M pieces of RAM is divided into address spaces which are numbered in sequence, and the timeslot is allocated by a timing generator of the scheduling module and a timeslot cycle is N.

At block 104, a second sub-module of the scheduling module may read data from the data storage, process the data read out and send the processed data.

According to various examples of the present disclosure, the FPGA chip may include N receiving modules which have the same processing functions and a scheduling module (hereinafter may be referred to as SCH module), in which N is greater than or equal to 1. The N receiving modules are numbered from 0 in sequence. For example, a receiving module of which a serial number is 0 may be denoted as receiving module 0, a receiving module of which a serial number is 1 may be denoted as receiving module 1, and so like. Each receiving module may include an IF interface, a FIFO buffer queue (hereinafter may be referred to as DATAQ), and a SELECT sub-module. The scheduling module may include a timing generator (hereinafter may be referred to as TIMERSLOT), a data storage (hereinafter may be referred to as BUFFER), and a MAC sub-module.

The data storage BUFFER of the scheduling module may for example be implemented by stitching M pieces of RAM, in which M is greater than or equal to 1. The bit width of each piece of RAM is B-bit. The M pieces of RAM are numbered from 0 in sequence. For example, a piece of RAM of which a serial number is 0 may be denoted as RAM 0, a piece of RAM of which a serial number is 1 may be denoted as RAM 1, and so on. Each piece of RAM is divided into several address spaces which are sequentially numbered from 0. For example, an address space of which a serial number is 0 may be denoted as address space 0, an address space of which a serial number is 1 may be denoted as address space 1, and so on. The RAM has a dual-port feature, i.e., the RAM can be either written or read. According to various examples of the present disclosure, a technical scheme of timeslot division is described, in which the timing generator TIMERSLOT of the scheduling module SCH allocates timeslots of which a cycle is N (which is the same as the number of the receiving modules). The allocated timeslots are numbered from 0 in sequence. For example, a timeslot of which a serial number is 0 may be denoted as timeslot 0, a timeslot of which a serial number is 1 may be denoted as timeslot 1, and so like. Each receiving module performs a writing operation to a single piece of RAM in the BUFFER within each timeslot, and each time each receiving module writes B-bit to one address space of the RAM. Serial numbers of pieces of RAM in the BUFFER to which the receiving modules perform the writing operation are different. In this case, a serial number of a RAM to which the receiving module 0 performs the writing operation is configured as an benchmark, and serial numbers of pieces of RAM to which subsequent receiving modules perform the writing operation are increased by 1 in turn. When the serial number of the RAM reaches M−1, the serial number may be numbered from 0 and then increased by 1 sequentially. For example, if a serial number of a RAM to which the receiving module 0 performs the writing operation is 2, e.g., denoted as RAM 2, serial numbers of pieces of RAM to which subsequent receiving modules perform the writing operation are increased by 1 in turn, i.e., RAM 3, RAM 4, and the like. When the serial number of the RAM reaches M−1, the serial number is numbered from 0 and then increased by 1 sequentially, i.e., RAM 0, RAM 1, etc.

With respect to a serial number of an address space of the RAM to which each receiving module performs the writing operation within each timeslot, a serial number of an address space to which the receiving module 0 performs the writing operation is configured as an benchmark, and serial numbers of address spaces to which subsequent receiving modules perform the writing operation are increased by 1 in turn.

When reading data from the BUFFER, the MAC sub-module may perform a reading operation to the M pieces of RAM each time and read data stored in one address space of each piece of RAM. In this case, serial numbers of the address spaces of the M pieces of RAM read by the MAC sub-module are the same. That is, the MAC sub-module performs the reading operation to the M pieces of RAM simultaneously and reads M×B-bit data each time. As such, the conversion from a smaller bit width to a larger bit width is realized and Look-Up-Table (LUT) resources are saved.

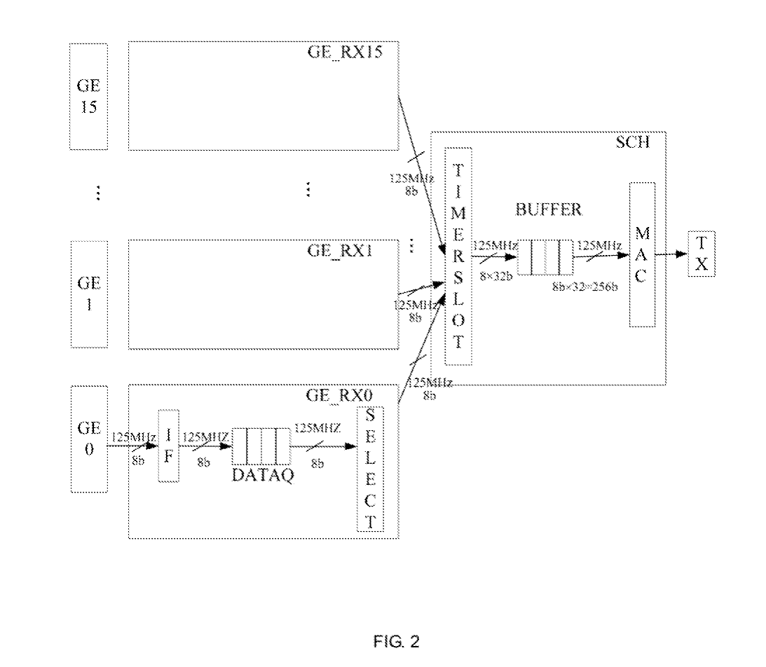

Taking 16 GE receiving modules as shown in FIG. 2 as an example, in which the BUFFER is constructed by 32 pieces of 8-bit RAM, specific operations may be described as follows.

For a GE receiving module of which a serial number is 0, e.g., denoted as GE_RX0:

at timeslot 0, the GE_RX0 may write address space 0 of each of RAM 0 and RAM 16;

at timeslot 1, the GE_RX0 may write address space 0 of each of RAM 1 and RAM 17; and so forth;

at timeslot 15, the GE_RX0 may write address space 0 of each of RAM 15 and RAM 31.

For a GE receiving module of which a serial number is 1, e.g., denoted as GE_RX1:

at timeslot 0, the GE_RX1 may write address space 1 of each of RAM 1 and RAM 17;

at timeslot 1, the GE_RX1 may write address space 1 of each of RAM 2 and RAM 18; and so forth;

at timeslot 15, the GE_RX1 may write address space 1 of each of RAM 0 and RAM 16.

Remaining receiving modules may operate accordingly.

For a GE receiving module of which a serial number is 15, e.g., denoted as GE_RX15:

at timeslot 0, the GE_RX15 may write address space 15 of each of RAM 15 and RAM 31;

at timeslot 1, the GE_RX15 may write address space 15 of each of RAM 16 and RAM 0; and so forth;

at timeslot 15, the GE_RX15 may write address space 15 of each of RAM 14 and RAM 30.

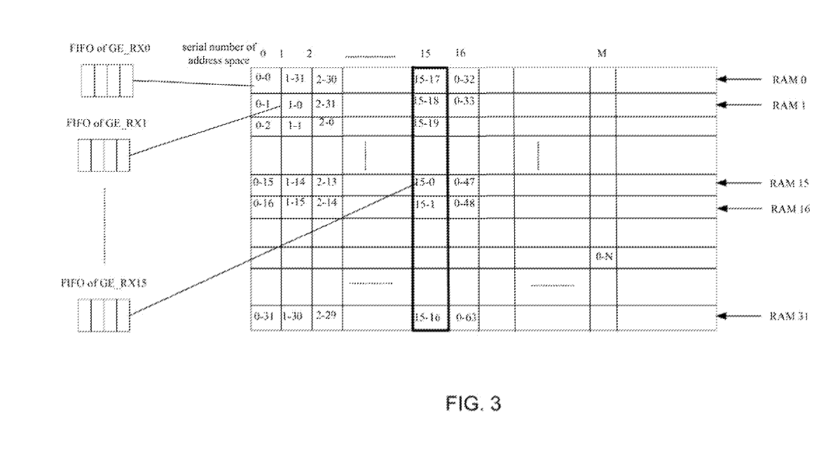

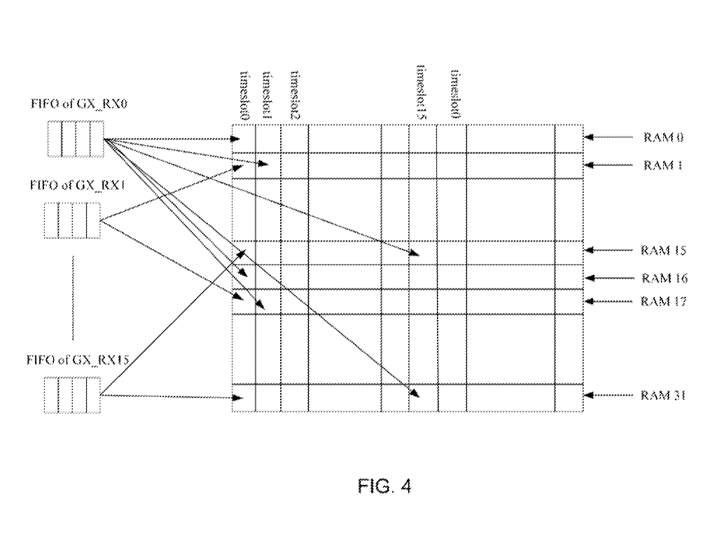

The storage space and timeslot operating process of the above example may be respectively shown in FIG. 3 and FIG. 4.

In the example, when the MAC sub-module reads data from the BUFFER, 32×8 bits are read each time, as illustrated by the crude wireframe shown in FIG. 3. The MAC sub-module performs the reading operation to the 32 pieces of RAM each time and reads data stored in one address space of each of the 32 pieces of RAM. In this case, serial numbers of the address spaces of the 32 pieces of RAM read by the MAC sub-module are the same. If the data read out is not the data which is stored in the BUFFER by the receiving module 0, shift processing may be performed to the data read out. For example, low S-byte of the original data read out may be configured as high S-byte of real data and high L-byte of the original data may be configured as low L-byte of the real data and S+L=M, in which L is a serial number of a receiving module corresponding to the data read out, i.e., the data read out is the data stored in the BUFFER by the receiving module of which the serial number is L. In the example, RAM 0 stores high bytes of the data and RAM 31 stores low bytes of the data. For example, when the MAC sub-module reads the data which is stored in the BUFFER by the receiving module GE_RX15, L is equal to 15 and S is equal to 17 since M is equal to 32. As such, low 17 bytes of the original data read out may be configured as high 17 bytes of real data and high 15 bytes of the original data may be configured as low 15 bytes of the real data, i.e., REAL_RDATA [255:0]={INI_RDATA [135:0], INI_RDATA [255:136]}, in which the data is valid from high-bit to low-bit.

Taking the reception functions of the 16 GE interfaces as an example, a method for implementing a high-bandwidth multiplexing function module is described as follows.

Assuming the functional diagram of the example is shown in FIG. 2, in which GE0-GE15 represent external interfaces, GE_RX0-GE_RX15 are 16 receiving modules with the same function, and SCH is the scheduling module. Each receiving module may for example consist of an IF interface, a FIFO DATAQ buffer, and a SELECT sub-module. The scheduling module SCH may for example consist of a TIMERSLOT sub-module, a BUFFER storage sub-module, and a MAC sub-module. In this case, the DATAQ buffer is implemented by a single piece of RAM of which a bit width is 8-bit. The BUFFER storage sub-module is constructed by 32 pieces of 8-bit RAM and the total bit width of the BUFFER is 256-bit. The receiving modules and the scheduling module work at 125 MHz. In FIG. 2, 125 MHz between the IF interface and the external interface and 125 MHz between the IF interface and the DATAQ buffer share a same clock source, while 125 MHz between sub-modules of the scheduling module belongs to another clock source. Data transfer between these two clock sources may be implemented through asynchronous FIFO.

In the example, each of the 16 external interfaces may transmit received data to a receiving module associated with the external interface. The IF interface may store the data received from the external interface to the DATAQ buffer. The scheduling module SCH may schedule data from the 16 GE receiving modules to the BUFFER according to a timeslot division method. Functions like ethernet frame data analysis, information extraction and statistics, CRC checking, etc. may be implemented through the GE MAC processing module. The external interface may send the data to the IF interface of the receiving module. The IF interface may store the data in the DATAQ buffer in accordance with a FIFO principle. The SELECT sub-module may operate the 32 pieces of RAM forming the BUFFER in the scheduling module SCH according to allocated timeslots. Each receiving module may write the data stored in the DATAQ buffer of the receiving module to the BUFFER storage sub-module in accordance with the FIFO principle.

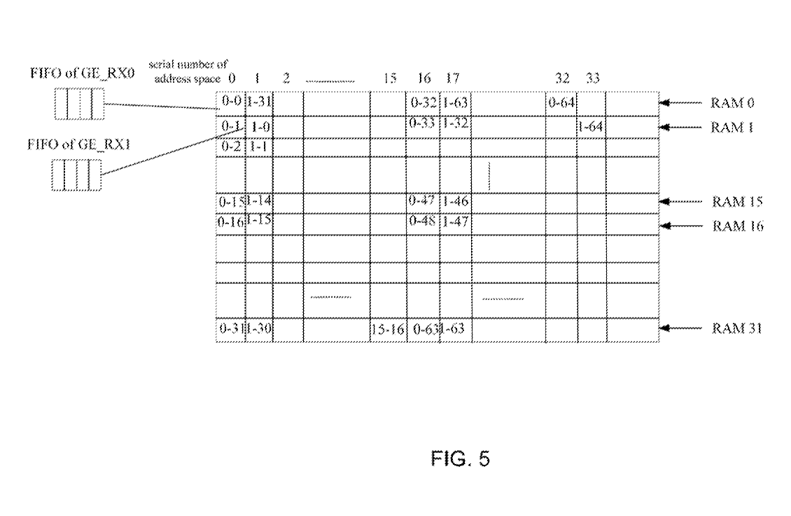

FIG. 5 is a diagram illustrating a data storage space of the example. As shown in FIG. 5, different address spaces of each piece of RAM are numbered from 0 in sequence. Taking the receiving modules GE_RX0 and GE_RX1 and a packet of which the length is 65 bytes as an example, bytes of the packet may be numbered from 0, i.e., the first byte of the packet is numbered as byte 0, the second byte of the packet is numbered as byte 1, and serial numbers of subsequent bytes are increased by 1 in turn. The 16 timeslots run periodically in accordance with clock ticks.

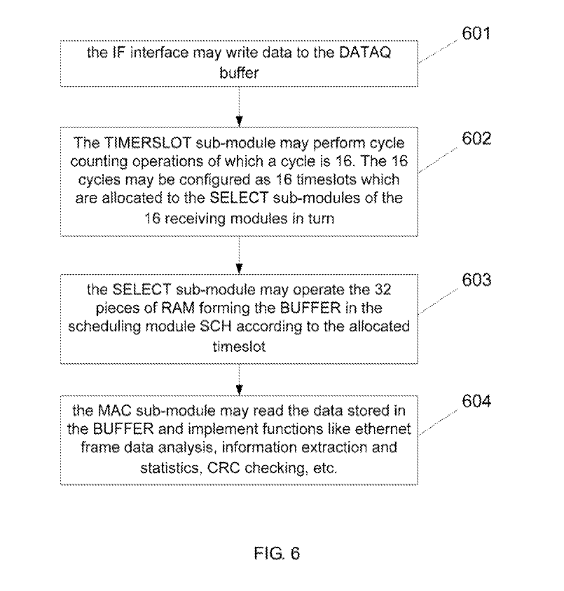

Based on the data storage space as shown in FIG. 5, FIG. 6 is a flowchart illustrating a method of saving resources through timeslot division, according to various examples of the present disclosure. As shown in FIG. 6, the method may include following operations.

At block 601, the IF interface may write data to the DATAQ buffer.

In this case, the receiving modules GE_RX0 and GE_RX1 respectively receive 65-byte data via the IF interface of each of GE_RX0 and GE_RX1. The GE_RX0 and GE_RX1 write the received 65-byte data to the DATAQ buffer of each of GE_RX0 and GE_RX1. Each receiving module writes 8-bit data every time and 65 bytes occupy 65 address spaces of the BUFFER. According to various examples of the present disclosure, the DATAQ buffer may for example be implemented by a single piece of RAM, in which the bit width of the RAM is 8-bit.

At block 602, the TIMERSLOT sub-module may perform cycle counting operations of which a cycle is 16, i.e., the cycle counting operation is performed 16 times. The 16 cycles may be configured as 16 timeslots which are allocated to the SELECT sub-modules of the 16 receiving modules in turn.

In this case, the timing generator of the scheduling module SCH, i.e., the TIMERSLOT sub-module allocates the timeslots and the cycle of the timeslot is 16. As such, the 16 receiving modules respectively write the data to a corresponding RAM in the BUFFER according to the allocated timeslot.

At block 603, the SELECT sub-module may operate the 32 pieces of RAM (which may for example be serially numbered as RAM 0, RAM 1, . . . RAM 31) forming the BUFFER in the scheduling module SCH according to the allocated timeslot. Specific operations are described as follows.

At timeslot 0, the receiving module GE_RX0 may operate address space 0 of RAM 0 and write byte 0 (denoted as 0-0) of the data packet received by GE_RX0 (hereinafter may be referred to as data packet 0). The receiving module GE_RX1 may operate address space 1 of RAM 1 and write byte 0 (denoted as 1-0) of the data packet received by GE_RX1 (hereinafter may be referred to as data packet 1).

At timeslot 1, the receiving module GE_RX0 may operate address space 0 of RAM 1 and write byte 1 (denoted as 0-1) of the data packet 0. The receiving module GE_RX1 may operate address space 1 of RAM 2 and write byte 1 (denoted as 1-1) of the data packet 1.

At timeslot 2, the receiving module GE_RX0 may operate address space 0 of RAM 2 and write byte 2 (denoted as 0-2) of the data packet 0. The receiving module GE_RX1 may operate address space 1 of RAM 3 and write byte 2 (denoted as 1-2) of the data packet 1, and so forth.

At timeslot 14, the receiving module GE_RX0 may operate address space 0 of RAM 14 and write byte 14 (denoted as 0-14) of the data packet 0. The receiving module GE_RX1 may operate address space 1 of RAM 15 and write byte 14 (denoted as 1-14) of the data packet 1.

At timeslot 15, the receiving module GE_RX0 may operate address space 0 of RAM 15 and write byte 15 (denoted as 0-15) of the data packet 0. The receiving module GE_RX1 may operate address space 1 of RAM 16 and write byte 15 (denoted as 1-15) of the data packet 1.

So far, the TIMERSLOT sub-module allocates timeslots within one cycle to the 16 receiving modules, i.e., one timeslot is allocated for each receiving module. The second timeslot cycle may begin from timeslot 0.

At timeslot 0, the receiving module GE_RX0 may operate address space 0 of RAM 16 and write byte 16 (denoted as 0-16) of the data packet 0. The receiving module GE_RX1 may operate address space 1 of RAM 17 and write byte 16 (denoted as 1-16) of the data packet 1, and so forth.

At timeslot 14, the receiving module GE_RX0 may operate address space 0 of RAM 30 and write byte 30 (denoted as 0-30) of the data packet 0. The receiving module GE_RX1 may operate address space 1 of RAM 31 and write byte 30 (denoted as 1-30) of the data packet 1.

At timeslot 15, the receiving module GE_RX0 may operate address space 0 of RAM 31 and write byte 31 (denoted as 0-31) of the data packet 0. The receiving module GE_RX1 may operate address space 1 of RAM 0 and write byte 31 (denoted as 1-31) of the data packet 1.

So far, the TIMERSLOT sub-module allocates timeslots within two cycles to the 16 receiving modules. The third timeslot cycle may begin from timeslot 0.

At timeslot 0, the receiving module GE_RX0 may operate address space 16 of RAM 0 and write byte 32 (denoted as 0-32) of the data packet 0. The receiving module GE_RX1 may operate address space 17 of RAM 1 and write byte 32 (denoted as 1-32) of the data packet 1, and so forth.

At timeslot 14, the receiving module GE_RX0 may operate address space 16 of RAM 14 and write byte 46 (denoted as 0-46) of the data packet 0. The receiving module GE_RX1 may operate address space 17 of RAM 15 and write byte 46 (denoted as 1-46) of the data packet 1.

At timeslot 15, the receiving module GE_RX0 may operate address space 16 of RAM 15 and write byte 47 (denoted as 0-47) of the data packet 0. The receiving module GE_RX1 may operate address space 17 of RAM 16 and write byte 47 (denoted as 1-47) of the data packet 1.

So far, the TIMERSLOT sub-module allocates timeslots within three cycles to the 16 receiving modules. The fourth timeslot cycle may begin from timeslot 0.

At timeslot 0, the receiving module GE_RX0 may operate address space 16 of RAM 16 and write byte 48 (denoted as 0-48) of the data packet 0. The receiving module GE_RX1 may operate address space 17 of RAM 17 and write byte 48 (denoted as 1-48) of the data packet 1, and so forth.

At timeslot 14, the receiving module GE_RX0 may operate address space 16 of RAM 30 and write byte 62 (denoted as 0-62) of the data packet 0. The receiving module GE_RX1 may operate address space 17 of RAM 31 and write byte 62 (denoted as 1-62) of the data packet 1.

At timeslot 15, the receiving module GE_RX0 may operate address space 16 of RAM 31 and write byte 63 (denoted as 0-63) of the data packet 0. The receiving module GE_RX1 may operate address space 17 of RAM 0 and write byte 63 (denoted as 1-63) of the data packet 1.

So far, the TIMERSLOT sub-module allocates timeslots within four cycles to the 16 receiving modules. The fifth timeslot cycle may begin from timeslot 0.

At timeslot 0, the receiving module GE_RX0 may operate address space 32 of RAM 0 and write byte 64 (denoted as 0-64) of the data packet 0. The receiving module GE_RX1 may operate address space 33 of RAM 1 and write byte 64 (denoted as 1-64) of the data packet 1.

So far, the 65-byte data received by the receiving module GE_RX0 and the 65-byte data received by the receiving module GE_RX1 are all stored in the BUFFER of the scheduling module SCH, the storage space as shown in FIG. 5. Referring to FIG. 5, the 65 bytes received by the receiving module GE_RX0 are stored in all of address spaces 0 of the 32 pieces of RAM, all of address spaces 16 of the 32 pieces of RAM, and address space 32 of RAM 0. The 65 bytes received by the receiving module GE_RX1 are stored in all of address spaces 1 of the 32 pieces of RAM, all of address spaces 17 of the 32 pieces of RAM, and address space 33 of RAM 0.

At block 604, the MAC sub-module may read the data stored in the BUFFER and implement functions like ethernet frame data analysis, information extraction and statistics, CRC checking, etc.

In this case, each time the MAC sub-module may read data stored in one address space of each of the 32 pieces of RAM, i.e., 32×8-bit=256-bit data may be read out each time.

When the data is read for the first time, the data stored in address space 0 of each of the 32 pieces of RAM is read out. The initial data read out INI_RDATA [255:0] may be configured as the real data REAL_RDATA [255:0] and may be directly processed.

When the data is read for the second time, the data stored in address space 1 of each of the 32 pieces of RAM is read out. As shown in FIG. 5, an order of the data bytes stored in all of the address spaces 1 is not an order of the data bytes stored in the BUFFER by the receiving module GE_RX1, therefore the shift processing may be performed to the initial data. For example, low 30 bytes of the initial data may be configured as high 30 bytes of the real data and high 1 byte of the initial data may be configured as low 1 byte of the real data, i.e., REAL_RDATA [255:0]={INI_RDATA [247:0], INI_RDATA [255:248]}. In this case, the data is valid from high-bit to low-bit. Similarly, when the data stored in all of the address spaces 17 is read, the same shift processing may be performed.

In the above examples, the technical scheme is described taking the data processing of the receiving modules GE_RX0 and GE_RX1 as an example. If 65-byte data received by the receiving module GE_RX15 is stored in the BUFFER and when the MAC sub-module read the data, the shift processing may be performed as follows. That is, low 17 bytes of the initial data may be configured as high 17 bytes of the real data and high 15 bytes of the initial data may be configured as low 15 bytes of the real data, i.e., REAL_RDATA [255:0]={INI_RDATA [135:0], INI_RDATA [255:136]}, in which the data is valid from high-bit to low-bit. The shift processing may refer to the corresponding descriptions in the above examples.

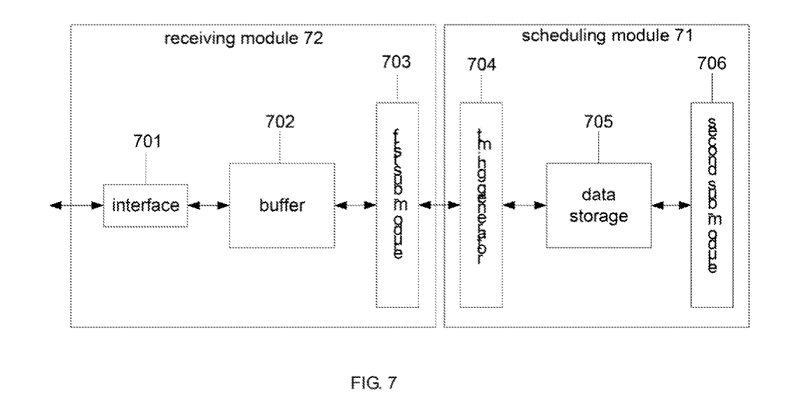

Various examples of the present disclosure describe a FPGA chip device. As shown in FIG. 7, the chip may include a scheduling module 71 and N receiving modules 72 which are numbered in sequence, in which N is greater than or equal to 1. For illustrative purposes, only one receiving module 72 is illustrated in FIG. 7.

Each receiving module 72 may include an interface 701, a First in First out (FIFO) buffer 702, and a first sub-module 703. The scheduling module 71 may include a timing generator 704, a data storage 705, and a second sub-module 706.

The interface 701 may receive data and write the data to the FIFO buffer 702.

The FIFO buffer 702 may store the data. In this case, the FIFO buffer is implemented by a single piece of RAM of which a bit width is B-bit.

The timing generator 704 may allocate timeslots, in which a timeslot cycle is N.

The first sub-module 703 may read B-bit data from the FIFO buffer 702 each timeslot, and write the B-bit data to the data storage 705.

The data storage 705 may store the data received from the first sub-module 703. In this case, the data storage 705 may for example be formed by M pieces of RAM which are numbered in sequence, each of the M pieces of RAM is divided into address spaces which are numbered in sequence.

The second sub-module 706 may read data from the data storage 705, process the data read out and send the processed data.

According to various examples of the present disclosure, the second sub-module 706 may perform a reading operation to the M pieces of RAM each time and read data stored in one address space of each of the M pieces of RAM. In this case, serial numbers of address spaces of the M pieces of RAM read by the second sub-module 706 are the same.

According to various examples of the present disclosure, the first sub-module 703 may perform a writing operation to a piece of RAM in the data storage 705 within each timeslot. In this case, serial numbers of pieces of RAM in the data storage 705 to which first sub-modules of the receiving modules perform the writing operation are different, a serial number of a piece of RAM to which a first sub-module of a first receiving module performs the writing operation is configured as an benchmark, and serial numbers of pieces of RAM to which first sub-modules of subsequent receiving modules perform the writing operation are increased by 1 in turn, when the serial number of the RAM reaches a maximum value, the serial number of the RAM is numbered from a serial number of a first piece of RAM and then increased by 1 sequentially.

According to various examples of the present disclosure, the first sub-module 703 may perform the writing operation to an address space of the RAM within each timeslot. In this case, a serial number of an address space to which the first sub-module of the first receiving module performs the writing operation is configured as an benchmark, and serial numbers of address spaces to which the first sub-modules of the subsequent receiving modules perform the writing operation are increased by 1 in turn.

According to various examples of the present disclosure, when the data read out from the data storage 705 through the second sub-module 706 is not data stored in the data storage 705 by a first receiving module, the second sub-module 706 may configure low S-byte of the data read out as high S-byte of real data, and configure high L-byte of the data read out as low L-byte of the real data, in which S+L=M. In this case, L is a serial number of a receiving module storing the data read out to the data storage 705.

The above-mentioned modules in the examples of the present disclosure may be deployed either in a centralized or a distributed configuration, and may be either merged into a single module, or further split into a plurality of sub-modules.

These modules may be software (e.g., machine readable instructions stored in a computer readable medium and executable by a processor), hardware (e.g., the processor of an Application Specific Integrated Circuit (ASIC)), or a combination thereof.

According to various examples of the present disclosure, a plurality of modules may share a data bus through timeslot division without using complicated port polling circuits. Multiple pieces of RAM may be called due to the dual-port feature of the RAM, so that each receiving module may write data with smaller bit width to a single piece of RAM in the data storage BUFFER each time and the MAC sub-module may simultaneously read data stored in the multiple pieces of RAM forming the BUFFER. As such, the conversion from a smaller bit width to a larger bit width is realized and LUT resources are saved.

The above examples may be implemented by hardware, software or firmware, or a combination thereof. For example, the various methods, processes and functional modules described herein may be implemented by a processor (the term processor is to be interpreted broadly to include a CPU, processing unit, ASIC, logic unit, or programmable gate array, etc.). The processes, methods, and functional modules disclosed herein may all be performed by a single processor or split between several processors. In addition, reference in this disclosure or the claims to a ‘processor’ should thus be interpreted to mean ‘one or more processors’. The processes, methods and functional modules disclosed herein may be implemented as machine readable instructions executable by one or more processors, hardware logic circuitry of the one or more processors or a combination thereof. Further the examples disclosed herein may be implemented in the form of a computer software product. The computer software product may be stored in a non-transitory storage medium and may include a plurality of instructions for making a computer apparatus (which may be a personal computer, a server or a network apparatus such as a router, switch, access point, etc.) implement the method recited in the examples of the present disclosure.

All or part of the procedures of the methods of the above examples may be implemented by hardware modules following machine readable instructions. The machine readable instructions may be stored in a computer readable storage medium. When running, the machine readable instructions may provide the procedures of the method examples. The storage medium may be diskette, CD, ROM (Read-Only Memory) or RAM (Random Access Memory), and etc.

The figures are only illustrations of examples, in which the modules or procedures shown in the figures may not be necessarily essential for implementing the present disclosure. The modules in the aforesaid examples may be combined into one module or further divided into a plurality of sub-modules.

What has been described and illustrated herein is an example of the disclosure along with some of its variations. The terms, descriptions and figures used herein are set forth by way of illustration only and are not meant as limitations. Many variations are possible within the spirit and scope of the disclosure, which is intended to be defined by the following claims and their equivalents in which all terms are meant in their broadest reasonable sense unless otherwise indicated.

What is claimed is:

1. A method for allocating a timeslot, applied to a Field-Programmable Gate Array (FPGA) chip, wherein the FPGA chip comprises a scheduling module and N receiving modules which are numbered in sequence, N is greater than or equal to 1, the method comprising:
receiving data by an interface of a receiving module;
writing the data to a buffer of the receiving module;
wherein the buffer is implemented by a single piece of random access memory (RAM) of which a bit width is B-bit;
reading, through a first sub-module of the receiving module, B-bit data from the buffer each timeslot and writing the B-bit data to a data storage of the scheduling module;
wherein the data storage is formed by M pieces of RAM which are numbered in sequence, each of the M pieces of RAM is divided into address spaces which are numbered in sequence, and the timeslot is allocated by a timing generator of the scheduling module and a timeslot cycle is N; and
reading, through a second sub-module of the scheduling module, data from the data storage, processing the data read out and sending the processed data.

2. The method of claim 1, wherein the operation of reading the data from the data storage through the second sub-module of the scheduling module comprises:
performing, by the second sub-module, a reading operation to the M pieces of RAM each time and reading data stored in one address space of each of the M pieces of RAM;
wherein serial numbers of address spaces of the M pieces of RAM read by the second sub-module are the same.

3. The method of claim 2, wherein the operation of reading, through the first sub-module of the receiving module, the B-bit data from the buffer each timeslot and writing the B-bit data to the data storage comprises:
performing, by each receiving module, a writing operation to a piece of RAM in the data storage within each timeslot;
wherein serial numbers of pieces of RAM in the data storage to which the receiving modules perform the writing operation are different, a serial number of a piece of RAM to which a first receiving module performs the writing operation is configured as an benchmark, and serial numbers of pieces of RAM to which subsequent receiving modules perform the writing operation are increased by 1 in turn, when the serial number of the RAM reaches a maximum value, the serial number of the RAM is numbered from a serial number of a first piece of RAM and then increased by 1 sequentially.

4. The method of claim 3, wherein the operation of performing, by each receiving module, the writing operation to a piece of RAM in the data storage within each timeslot comprises:
performing, by each receiving module, the writing operation to an address space of the RAM within each timeslot;
wherein a serial number of an address space to which the first receiving module performs the writing operation is configured as an benchmark, and serial numbers of address spaces to which the subsequent receiving modules perform the writing operation are increased by 1 in turn.

5. The method of claim 1, further comprising:
when the data read out from the data storage through the second sub-module of the scheduling module is not data stored in the data storage by a first receiving module, configuring low S-byte of the data read out as high S-byte of real data, and configuring high L-byte of the data read out as low L-byte of the real data, wherein S+L=M;
wherein L is a serial number of a receiving module storing the data read out to the data storage.

6. A Field-Programmable Gate Array (FPGA) chip, comprising a scheduling module and N receiving modules which are numbered in sequence, wherein N is greater than or equal to 1;
wherein each receiving module comprises an interface, a buffer, and a first sub-module; the scheduling module comprises a timing generator, a data storage, and a second sub-module;
wherein
the interface is to receive data and write the data to the buffer;
the buffer is to store the data; wherein the buffer is implemented by a single piece of random access memory (RAM) of which a bit width is B-bit;
the timing generator is to allocate timeslots; wherein a timeslot cycle is N;
the first sub-module is to read B-bit data from the buffer each timeslot, and write the B-bit data to the data storage;
the data storage is to store the data received from the first sub-module; wherein the data storage is formed by M pieces of RAM which are numbered in sequence, each of the M pieces of RAM is divided into address spaces which are numbered in sequence; and
the second sub-module is to read data from the data storage, process the data read out and send the processed data.

7. The chip of claim 6, wherein the second sub-module is further to:
perform a reading operation to the M pieces of RAM each time and read data stored in one address space of each of the M pieces of RAM;
wherein serial numbers of address spaces of the M pieces of RAM read by the second sub-module are the same.

8. The chip of claim 7, wherein the first sub-module is further to:
perform a writing operation to a piece of RAM in the data storage within each timeslot;
wherein serial numbers of pieces of RAM in the data storage to which first sub-modules of the receiving modules perform the writing operation are different, a serial number of a piece of RAM to which a first sub-module of a first receiving module performs the writing operation is configured as an benchmark, and serial numbers of pieces of RAM to which first sub-modules of subsequent receiving modules perform the writing operation are increased by 1 in turn, when the serial number of the RAM reaches a maximum value, the serial number of the RAM is numbered from a serial number of a first piece of RAM and then increased by 1 sequentially.

9. The chip of claim 8, wherein the first sub-module is further to:
perform the writing operation to an address space of the RAM within each timeslot;
wherein a serial number of an address space to which the first sub-module of the first receiving module performs the writing operation is configured as an benchmark, and serial numbers of address spaces to which the first sub-modules of the subsequent receiving modules perform the writing operation are increased by 1 in turn.

10. The chip of claim 6, wherein the second sub-module is further to:
when the data read out from the data storage through the second sub-module is not data stored in the data storage by a first receiving module, configure low S-byte of the data read out as high S-byte of real data, and configure high L-byte of the data read out as low L-byte of the real data, wherein S+L=M;
wherein L is a serial number of a receiving module storing the data read out to the data storage.
